(19) United States
(12) Patent Application Publication
(10) Pub. No.: US 2026/0168084 A1
(43) Pub. Date: Jun. 18, 2026

(54) METHOD OF DEPOSITING MOLYBDENUM-CONTAINING MATERIAL ON A SURFACE

(71) Applicant: ASM IP Holding B.V., Almere (NL)

(72) Inventors: Jan Willem Maes, Wilrijk (BE); Chiyu Zhu, Helsinki (FI); Sukanya Datta, Phoenix, AZ (US); Sivaranjani Arumugam, Tokyo (JP); Hideaki Fukuda, Tokyo (JP); Mathieu Patrice Diers, Tokyo (JP)

(21) Appl. No.: 19/417,687

(22) Filed: Dec. 12, 2025

Related U.S. Application Data
(60) Provisional application No. 63/734,394, filed on Dec. 16, 2024.

(51) Int. Cl. C23C 16/04; C23C 16/02; C23C 16/455; C23C 16/56

(52) U.S. Cl. CPC C23C 16/045; C23C 16/0236; C23C 16/45536; C23C 16/45553; C23C 16/56

(57) ABSTRACT

Methods and systems of depositing molybdenum-containing material are disclosed. Exemplary methods can be used to form structures that include a conductive contact, a barrier layer, and/or a spacer using the deposited molybdenum-containing material.

### CROSS-REFERENCE TO RELATED APPLICATIONS

This application claims priority to U.S. Provisional Patent Application Ser. No. 63/734,394 filed Dec. 16, 2024 titled METHOD OF DEPOSITING MOLYBDENUM-CONTAINING MATERIAL ON A SURFACE, the disclosure of which is hereby incorporated by reference in its entirety.

### FIELD OF INVENTION

The present disclosure generally relates to methods of depositing material on a substrate surface. More particularly, the disclosure relates to methods of depositing molybdenum-containing material on a surface of a substrate.

### BACKGROUND OF THE DISCLOSURE

Conductive features, such as contacts, conductive plugs, lines, and the like, are often formed during the manufacture of electronic devices, such as semiconductor devices. The conductive features are often formed by depositing layers of conductive material, such as tungsten or copper, which can be formed within vias and/or etched to form the conductive features.

The conductive features are often formed on and/or within insulating or dielectric material on a substrate. Tungsten and copper can diffuse through dielectric and insulating materials that are typically used in the manufacture of electronic devices. Accordingly, manufacturing techniques that employ deposition of tungsten or copper often include use of barrier layers, such as titanium nitride, to mitigate diffusion of tungsten, copper, or the like, thereby improving device reliability and device yield. However, the barrier layer commonly exhibits a high electrical resistivity and therefore results in an increase in the overall electrical resistivity of the conductive feature. Furthermore, formation of a barrier layer adds to a complexity of forming conductive features and generally requires additional equipment. For example, a barrier layer is often formed in one reaction chamber and the conductive layer or feature (e.g., copper or tungsten) is formed in another reaction chamber. Accordingly, improved methods of forming conductive features are desired.

Additionally, in some applications, it may be desirable to form a low resistance contact to a semiconductive surface, such as a silicon surface. Typical contacts can include titanium/titanium nitride contacts or nickel/nickel platinum contacts. While such contacts can work for a variety of applications, techniques to form contacts with such materials can include an undesirable number of steps and/or a resistance of the contacts may be undesirably high. Accordingly, improved techniques for forming a contact are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of exemplary embodiments of the disclosure below. This summary is not intended to necessarily identify key features or essential features of the claimed subject matter, nor is it intended to be used to limit the scope of the claimed subject matter.

Various embodiments of the present disclosure relate to methods of depositing molybdenum. Exemplary methods can be used to, for example, fill a recess on a surface of a substrate, form a barrier layer, and/or form a contact to, e.g., a semiconductive surface, with molybdenum-containing material. Such methods can be used to form structures suitable for use in forming electronic devices, such as semiconductor devices.

While the ways in which various embodiments of the present disclosure address drawbacks of prior methods are discussed in more detail below, in general, embodiments of the disclosure provide improved methods that include plasma-assisted deposition at relatively low temperatures to obtain deposited molybdenum-containing material with desired properties. As set forth in more detail below, in some cases, examples of the disclosure can be used to at least partially fill a gap or recess on a substrate surface. Use of plasma-assisted deposition allows selective or non-selective deposition of molybdenum and deposition of molybdenum with desired properties. The plasma-assisted deposition can be used to form a molybdenum liner, to fill a gap, both, or the like.

In accordance with embodiments of the disclosure, a method of filling a recess on a surface of a substrate with a molybdenum-containing material is provided. The method includes providing a substrate in a reactor and forming a molybdenum-containing film by repeating a cycle comprising: supplying a first source gas comprising a molybdenum to the substrate, supplying a first reactant to the substrate, and applying a first power to the reactor to form a plasma to form activated reactant species that react with the first source gas or a derivative thereof that may be adsorbed on the substrate. In accordance with examples of these embodiments, the steps of supplying the first reactant and applying the first plasma power overlap in time. In accordance with further examples of the disclosure, the first source gas includes one or more of a molybdenum halide, a molybdenum oxyhalide, metal organic compounds (e.g., β-diketonates), or organometallic compounds. The first reactant can include at least one of hydrogen, nitrogen, or a mixture thereof. In accordance with additional examples, the method further includes supplying a second reactant—e.g., before applying the first power to the reactor. In accordance with yet further examples, the method can include performing a preclean to remove a native oxide from the substrate before forming the molybdenum-containing film. In accordance with yet additional examples, the method can include supplying a second source gas. The second source gas can comprise silicon. In these cases, the molybdenum-containing material can be a silicon and molybdenum-containing film. The method can additionally or alternatively include treating the substrate with a hydrogen while applying a second power before forming the molybdenum-containing film, after forming the molybdenum-containing film, or both. An exemplary method can further include performing a thermal anneal after forming the molybdenum-containing film; this step can be followed by performing chemical-mechanical polishing (CMP).

In accordance with additional embodiments of the disclosure, a method of filling a recess on a surface of a substrate with a molybdenum-containing material includes providing a substrate in a reactor, performing a preclean to clean a surface of the substrate, and forming a molybdenum-containing film conformally on a surface of the recess. The step of forming the molybdenum-containing film can include repeating a cycle comprising: supplying a first source gas comprising molybdenum to the substrate, supplying a first reactant to the substrate, and providing a first power to form activated species from the first reactant. The method can further include forming a metallic film on the molybdenum-containing film to fill the recess. The forming the metallic film step can include: supplying a metallic source gas to the substrate and supplying a second reactant to the substrate. The first reactant can be or include at least one of hydrogen, nitrogen, or a mixture thereof. The second reactant can be or include at least one of H₂, diiodoethane (C₂H₂I₂), silane, alkyl silane, alkyl iodide, silicon iodide, or a mixture thereof. The method can further include performing a thermal anneal after filling the recess; the anneal can be followed by performing CMP. In some cases, the method can include forming a capping layer on the molybdenum-containing film, followed by a thermal annealing.

In accordance with yet additional embodiments of the disclosure, a method of forming a molybdenum-containing film on a surface of a recess on a substrate surface includes forming a molybdenum-containing film by repeating a cycle that includes supplying a source gas comprising a molybdenum to the substrate, supplying a reactant to the substrate, and forming a plasma by applying a power to the reactor, wherein the source gas is halogen-free. The reactant can be or include at least one of hydrogen, nitrogen, or a mixture thereof.

These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates another method in accordance with exemplary embodiments of the disclosure.

FIG. 3 illustrates another method in accordance with exemplary embodiments of the disclosure.

FIG. 4 illustrates another method in accordance with exemplary embodiments of the disclosure.

FIGS. 5-8 illustrate timing sequences suitable for use with various methods in accordance with additional exemplary embodiments.

FIGS. 9-12 illustrate structures in accordance with further embodiments of the disclosure.

FIG. 13 illustrates a substrate in accordance with exemplary embodiments of the disclosure.

FIG. 14 illustrates a TEM image of structures in accordance with exemplary embodiments of the disclosure.

FIG. 15 illustrates film properties versus plasma power on time of molybdenum-containing material deposited in accordance with examples of the disclosure.

FIG. 16 illustrates effects of nitrogen flow on crystallinity of molybdenum-containing material deposited in accordance with examples of the disclosure.

FIG. 17 illustrates a system in accordance with yet additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure. Further, the illustrations presented herein are not necessarily meant to be actual views of any particular material, structure, or device, but are merely representations that are used to describe embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Moreover, recitation of multiple embodiments having stated features is not intended to exclude other embodiments having additional features or other embodiments incorporating different combinations of the stated features. Unless otherwise noted, the exemplary embodiments or components thereof may be combined in various combinations or may be applied separate from each other. For example, while pre-clean, treatment, anneal, and/or polishing steps may be described in connection with particular examples, such processes can be used with other illustrative examples.

As set forth in more detail below, embodiments of the disclosure relate to a method of filling a recess on a surface of a substrate with a molybdenum-containing material and/or a method of forming a molybdenum-containing film on a surface of a recess on a substrate surface. Exemplary methods can be used to at least partially fill a gap on a surface of a substrate. Exemplary embodiments described herein may be particularly suitable for use in front end of line (FEOL), middle of line (MOL), and/or back end of line (BEOL) processes used to form electronic devices. For example, the methods can be used to deposit molybdenum that is suitable for applications, such as, for example, low electrical resistivity gap-fill layers for logic and memory devices. Exemplary methods provide molybdenum (e.g., in a gap) that exhibits relatively low effective electrical resistivity and/or other desired properties noted herein. The deposited molybdenum can be used to, for example, form a contact within a via and/or as a barrier layer and/or as a spacer.

In this disclosure, gas can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term precursor can refer to a compound that participates in the chemical reaction that produces another compound, and particularly to a compound that constitutes a film matrix or a main skeleton of a film; the term reactant can be used to refer to a gas that reacts with the precursor or derivative thereof to form a desired material (e.g., molybdenum-containing material). In some cases, the term reactant can be used interchangeably with the term precursor. Source gas can be a synonym for precursor. The term inert gas can refer to a gas that does not take part in a chemical reaction and/or does not become a part of a film matrix to an appreciable extent. Exemplary inert gases include helium, argon, and any combination thereof.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material. As described in more detail below, the dielectric layer can include one or more recesses.

As used herein, the term film and/or layer can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some cases, a film or layer may form conductive features, such as contacts, on a surface of a substrate.

As used herein, a structure can be or include a substrate as described herein. Structures can include features (e.g., recesses) and one or more layers overlying the features, such as one or more layers formed according to a method as described herein. A device can include or be formed using a structure.

As used herein, chemical vapor deposition (CVD) can refer to a vapor deposition process in which volatile precursors and/or reactants react and/or decompose on a surface of a substrate. During a typical CVD process, a precursor and a reactant can be flowed to a reaction chamber during an overlap period, during which both the precursor and the reactant are provided to the reaction chamber.

As used herein, the term cyclic deposition can refer to the sequential introduction of one or more precursors and/or reactants into a reaction chamber to deposit a film over a substrate and include deposition techniques, such as atomic layer deposition and cyclical chemical vapor deposition. In some cases, a cyclic deposition process can include continuously providing a plasma power, precursor, reactant and/or an inert gas to a reaction chamber and pulsing other of a precursor, reactant, inert gas and/or plasma power to the reaction chamber. Such processes can be referred to as cyclical chemical vapor deposition or pulsed chemical vapor deposition. Various examples of cyclical processes are described in more detail below.

As used herein, the term molybdenum precursor refers to a precursor that comprises molybdenum. A halogen-free source gas does not include a halogen.

As used herein, the term molybdenum halide precursor refers to a precursor that includes molybdenum and at least one halogen. The halogen can include one or more of chlorine, iodine, and bromine.

As used herein, the term molybdenum chalcogenide halide refers to a precursor that includes a molybdenum, a halogen, and a chalcogen. The chalcogen can include one or more of oxygen (O), sulfur(S), selenium (Se), and tellurium (Te).

As used herein, the term molybdenum oxyhalide refers to a precursor that includes molybdenum, oxygen, and at least one halogen.

As used herein, the term reducing agent can refer to a reactant that donates an electron to another species in a chemical reaction.

As used herein, the term recess can refer to an opening or cavity disposed between surfaces of a non-planar structure. The term recess can refer to an opening or cavity disposed between opposing inclined sidewalls of two protrusions extending vertically from the surface of the substrate or within an indentation (e.g., having a single sidewall) extending vertically into the surface of the substrate; such recesses can be referred to as vertical recesses. The sidewall can be substantially perpendicular to a surface (e.g., bottom and/or top) or can be sloped. The term recess can also refer to an opening or cavity disposed between two opposing substantially horizontal surfaces or between two opposing substantially horizontal portions of a surface, the horizontal surfaces bounding at least a portion of the horizontal opening or cavity; such recesses may be referred to as horizontal gaps. The sidewalls between the opposing substantially horizontal surfaces or portions can be perpendicular to the surfaces or portions or can be sloped.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like in some embodiments. Further, in this disclosure, the terms “including,” “constituted by” and “having” and related words can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicated herein can be relative or absolute percentages. The term about can mean +/−20, 10, 5, 2, 1, or 0.5% of a stated dimension, direction, shape, value or the like.

Although a number of example materials are given throughout the embodiments of the current disclosure, it should be noted that the chemical formulas given for each of the example materials should not be construed as limiting and that the non-limiting example materials given should not be limited by a given example stoichiometry.

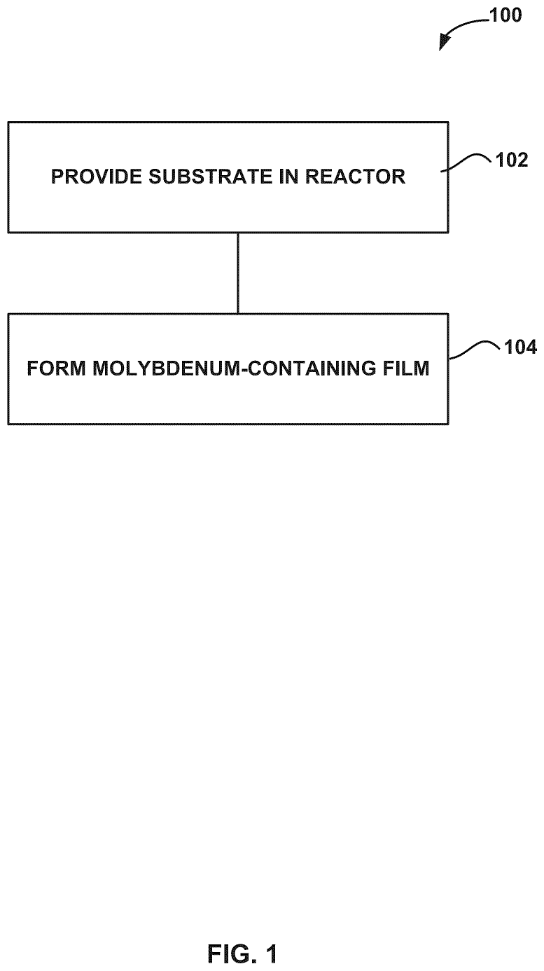

Turning now to the figures, FIG. 1 illustrates a method 100 (e.g., of filling a recess on a surface of a substrate with a molybdenum-containing material and/or of forming a molybdenum-containing film on a surface of a recess) in accordance with exemplary embodiments of the disclosure. Method 100 includes the steps of providing a substrate (102) and forming a molybdenum-containing film (104).

During step 102, a substrate is provided within a reaction chamber. The substrate can include any substrate as described herein. By way of particular examples, the substrate includes a surface that includes a recess. The substrate can be suitable for FEOL, MOL and/or BEOL processing.

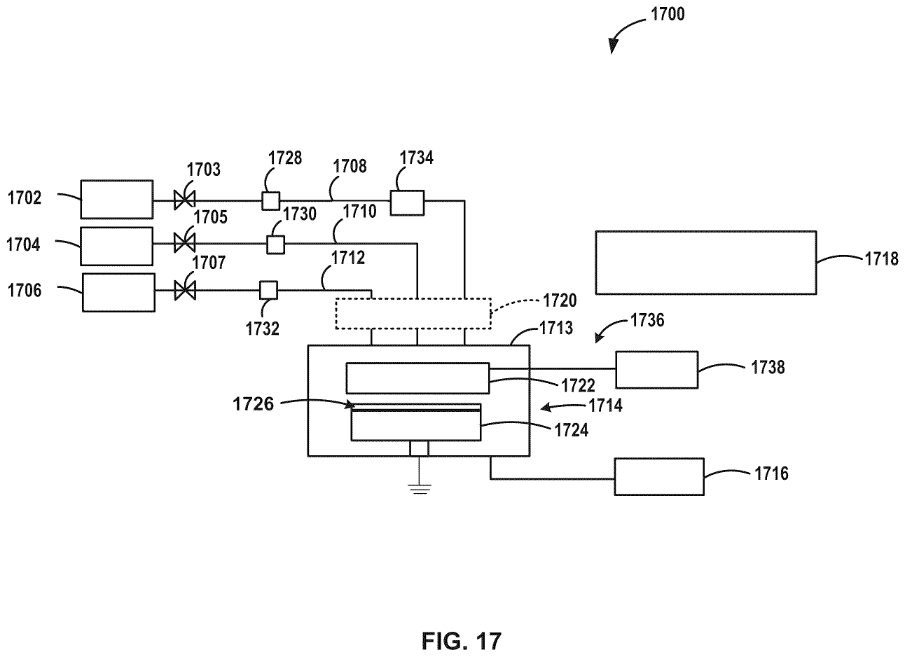

The reaction chamber used during step 102 can be or include a reaction chamber of a plasma-enhanced chemical vapor deposition reactor system configured to perform a method as described herein. The reaction chamber can be a standalone reaction chamber or part of a cluster tool or module. An exemplary reaction chamber suitable for use with method 100 is described in more detail below in connection with FIG. 17.

Step 102 can include heating the substrate to a desired deposition temperature within the reaction chamber. In some embodiments of the disclosure, step 102 includes heating the substrate to a temperature of less than 450° C., less than 400° C., less than 325° C., or less than 300° C. Additionally or alternatively, step 102 can include heating the substrate to a temperature greater than 200 ° C., greater than 275° C., or greater than 300° C. For example, the temperature can be between about 200° C. and 450° C. or between about 250° C. and 400° C. or between about 200 ° C. and about 400° C.

In addition to controlling the temperature of the substrate, a pressure within the reaction chamber may also be regulated. For example, in some embodiments of the disclosure, the pressure within the reaction chamber during step 102 may be less than 760 Torr or between about 1 Torr and about 10 Torr.

In accordance with examples of the disclosure, the substrate includes a surface comprising a first material and a second material. In some cases, the first material and the second material can be the same. In other cases, the second material is different than the first material. In some cases, the first material and the second material can define sections of a feature, such as a recess on the surface of the substrate.

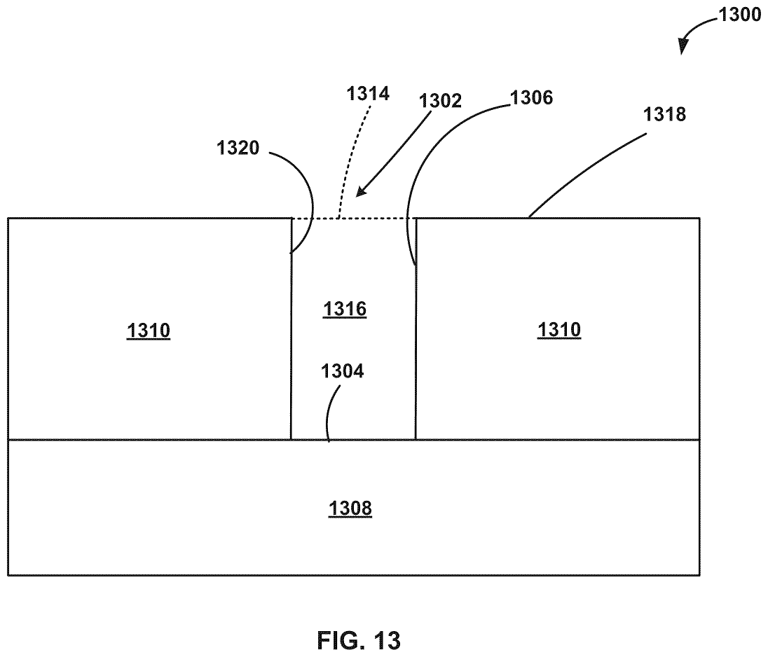

FIG. 13 illustrates a substrate 1300 including a recess 1302 suitable for use during step 102. In the illustrated example, the recess 1302 includes a first surface 1304 (e.g., at a bottom of the recess) comprising the first material and a second surface 1306 (e.g., on a sidewall 1320 of the recess and top surface 1318 of substrate 1300) comprising the second material, and a volume 1316. In the illustrated example, a volume 1316 is defined by the first surface 1304, the second surface 1306, and an imaginary line 1314 across a top of gap 1302.

The recess 1302 is illustrated as a vertical gap or recess. An aspect ratio (height: width) of recess 1302 can be greater than 2:1, or greater than 5:1, or greater than 10:1, or greater than 25:1, or greater than 50:1, or even greater than 100:1. In some embodiments of the disclosure, the substrate may comprise one or more substantially horizontal gaps or recesses, wherein the horizontal gap may have an aspect ratio (height: width) that may be greater than 2:1, or greater than 5:1, or greater than 10:1, or greater than 25:1, or greater than 50:1. In some cases, the aspect ratio is less than 200:1, less than 150:1, less than 100:1 or less than 50:1.

In the example illustrated in FIG. 13, the substrate 1300 includes an insulating (e.g., dielectric) material 1310. In accordance with examples of the disclosure, the insulating material 1310 can be or include a dielectric material, such as an oxide, or a nitride, such as silicon oxide or silicon nitride, or low-k dielectric material, such as a metal oxide. In some embodiments, the insulating material 1310 can be or include one or more of silicon dioxide (SiO₂), non-stoichiometric silicon oxide, silicon nitride (Si₃N₄), non-stoichiometric silicon nitride, silicon oxynitride (SiON), silicon oxycarbide (SiOC), silicon oxycarbon nitride (SiOCN), silicon carbon nitride (SiCN), or the like. In some embodiments, the insulating material 1310 can be or include a low dielectric constant dielectric material, such as one or more of aluminum oxide (Al₂O₃), hafnium oxide (HfO₂), tantalum oxide (Ta₂O₅), zirconium oxide (ZrO₂), titanium oxide (TiO₂), hafnium silicate (HfSiOₓ), lanthanum oxide (La₂O₃), or the like.

As illustrated, the second surface 1306 can be a surface of the insulating material 1310. Further, the second surface 1306 can extend to the top surface 1318 of insulating material 1310 and/or of substrate 1300. In other words, the second material can be or include the insulating material 1310.

The substrate 1300 also includes a material 1308 at a bottom of recess 1302. The material 1308 can be or include, for example, semiconductive material. The semiconductive material can be or include, for example, silicon, or silicon germanium doped with at least one of phosphorous (P), boron (B), gallium (Ga), arsenide (As), antimony (Sb), or a mixture thereof, or the like. In other cases, the material 1308 can be conductive. In these cases, the material 1308 can include, for example, a metal, such as tungsten, molybdenum, or the like, and/or a metal nitride, such as tungsten nitride, titanium nitride, or the like. The first surface 1304 can be or include the same material as the material 1308. In other words, the first material comprising the first surface 1304 can be or include a semiconductive or conductive material.

Referring again to FIG. 1, in accordance with examples of the disclosure, step 104 includes forming a molybdenum-containing film. The molybdenum-containing film can be formed by, for example, supplying a first source gas comprising a molybdenum to the substrate, supplying a first reactant to the substrate, and applying a first power to the reactor to form a plasma to form activated reactant species that react with the first source gas or a derivative thereof in the gas phase and/or adsorbed on the substrate. In accordance with examples of these embodiments, the steps of supplying the first reactant and applying the first plasma power overlap in time.

In accordance with examples of the disclosure, step 104 is non-selective and/or conformal, such that molybdenum is deposited relatively evenly overlying and in contact with a first material (e.g., a material 1308) and a second material (e.g., a material 1310). A selectivity of a process can be expressed as a ratio of material deposited (e.g., a layer thickness) on the first surface relative to the amount of material (e.g., a layer thickness) formed on the first and second surfaces combined. For example, if 10 nm of molybdenum is deposited on first surface 1304 and 10 nm of molybdenum is deposited on second surface 1306/1318, the selective deposition process will be considered to be non-selective with a 50% selectivity. In accordance with examples of the disclosure, a selectivity of the deposited molybdenum-containing material on the first material relative to the second material is between about 40 percent and about 60 percent or between about 45 percent and about 55 percent. Additionally or alternatively, a selectivity of the plasma-deposited molybdenum can be greater than 70%, greater than 80%, greater than 90%, or greater than 95% conformal over the first and second surfaces. As described in more detail below, in accordance with other examples, the deposition may be selective and/or non-conformal.

A temperature and pressure within the reaction chamber during step 104 can be as described above in connection with step 102.

Exemplary first source gases suitable for use with step 104 include molybdenum precursors, such as molybdenum halide precursors and/or molybdenum metal organic or organometallic compounds. The molybdenum halide precursors can include one or more of a molybdenum chloride precursor, a molybdenum iodide precursor, a molybdenum bromide precursor, and the like. By way of examples, the first source gas can be or include at least one of MoO₂Cl₂, MoCl₄, MoCl₅, MoF₅, MoCO₆, MoO₂Br₂, tris(2,2,6,6-tetramethylheptane-3,5-dionato)molybdenum [Mo(thd)₃], bis(ethylbenzene)molybdenum [Mo(EtBz)₂], amide-based molybdenum source, cyclopentadienyl molybdenum [MoCp]-based molybdenum source, dicarbonyl[(1,2,3,4,5-η)-1-methyl-2,4-cyclopentadien-1-yl]nitrosylmolybdenum [CH₃C₅H₄Mo(CO)₂NO], or a mixture thereof.

A flowrate of the first source gas to the reaction chamber can be controlled and can be greater than zero and less than 1000 sccm, or less than 500 sccm, or less than 100 sccm, or less than 10 sccm, or even less than 1 sccm. For example, the flowrate can be between about 1 and 2000 sccm, between about 5 and 1000 sccm, or between about 10 and about 500 sccm. In some embodiments of the disclosure, for example, in the case of cyclical processes, the first source gas can be pulsed to the reaction chamber. In such cases, the reactant and/or an inert gas can be supplied continuously or can be pulsed. A duration of each first source gas pulse can be, for example, between about 0.1 and about 10 seconds.

In accordance with examples of the disclosure, a first source gas may be purged from the reaction chamber—e.g., after each pulse and/or upon completion of a deposition step. A purge can be effected either in time or in space, or both. For example, in the case of temporal purges, a purge step can be used, e.g., in the temporal sequence of providing a first source gas to a reactor chamber, ceasing a flow of the first source gas to the reaction chamber, providing a purge gas to the reactor chamber, and providing a reactant to the reactor chamber, wherein the substrate on which a material is deposited does not move. As noted herein, in some cases, the reactant can be used as a purge gas when the precursor is not flowing to the reaction chamber. In the case of spatial purges, a purge step can take the following form: moving a substrate from a first location to which a first source gas is (e.g., continually) supplied, through a purge gas curtain, to a second location to which a reactant is (e.g., continually) supplied. Purging times may be, for example, from about 0.01 seconds to about 20 seconds, from about 0.05 seconds to about 20 seconds, or from about 1 second to about 20 seconds, or from about 0.5 seconds to about 10 seconds, or between about 1 second and about 7 seconds.

Exemplary (e.g., first) reactants suitable for use with step 104 include reactants that include at least one of hydrogen, nitrogen, or a mixture thereof. By way of examples, the first reactant can be or include one or more of Ar, H₂, NH₃, NH₄, N₂H₄, B₂H₆, N₂, silane, alone or any mixture thereof.

A flowrate of the (e.g., first) reactant to the reaction chamber can be greater than zero and less than 100 slm, or less than 15 slm, or less than 10 slm, or less than 5 slm, or less than 1 slm, or even less than 0.1 slm. For example, the flowrate can be between about 0.1 to 30 slm, from about 5 to 15 slm, or equal to or greater than 10 slm. In the case of cyclical deposition processes, the reactant can be pulsed—e.g., for a duration between about 0.01 seconds and about 180 seconds, between about 0.05 seconds and about 60 seconds, or between about 0.1 seconds and about 30 seconds. As noted herein, in some cases, the reactant can be continuously flowed through one or more deposition cycles.

In some cases, a purge can be employed to remove any excess reactant and/or reaction byproducts from a reaction chamber—e.g., after a reactant pulse and/or at a completion of a deposition step. The purge can be as described above.

In accordance with examples of the disclosure, during step 104, a plasma is formed within the reaction chamber. The plasma can be formed while providing the molybdenum precursor and/or while providing the first reactant and/or while providing an inert gas. An inert gas, such as argon and/or helium, can be provided during step 104 to facilitate plasma formation. A flowrate of the inert gas can be between about 500 sccm and about 5000 sccm or between about 1000 and about 3000 sccm.

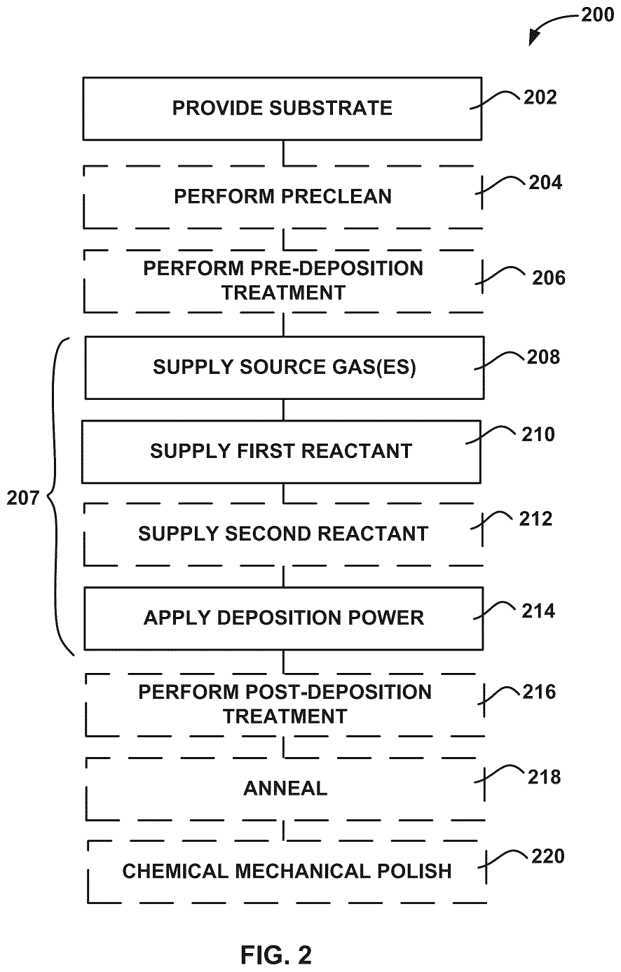

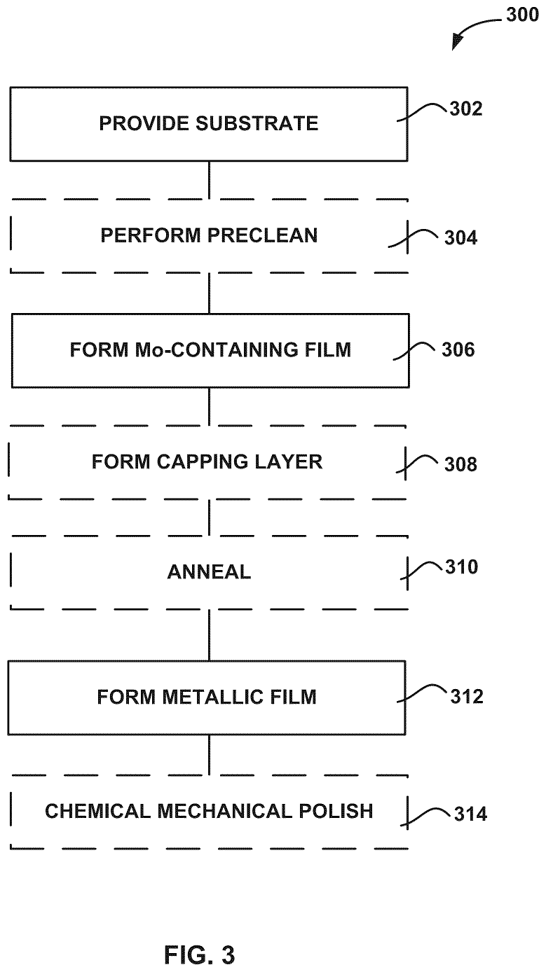

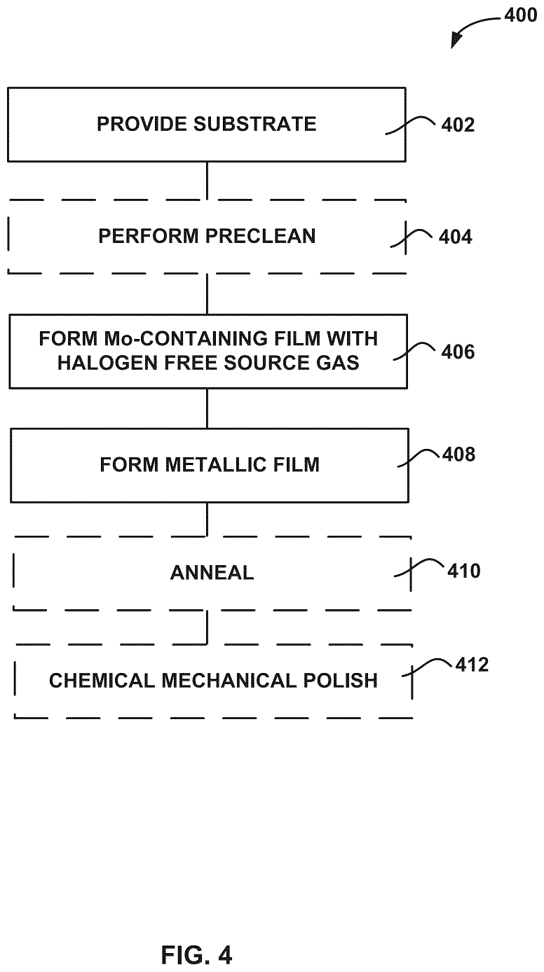

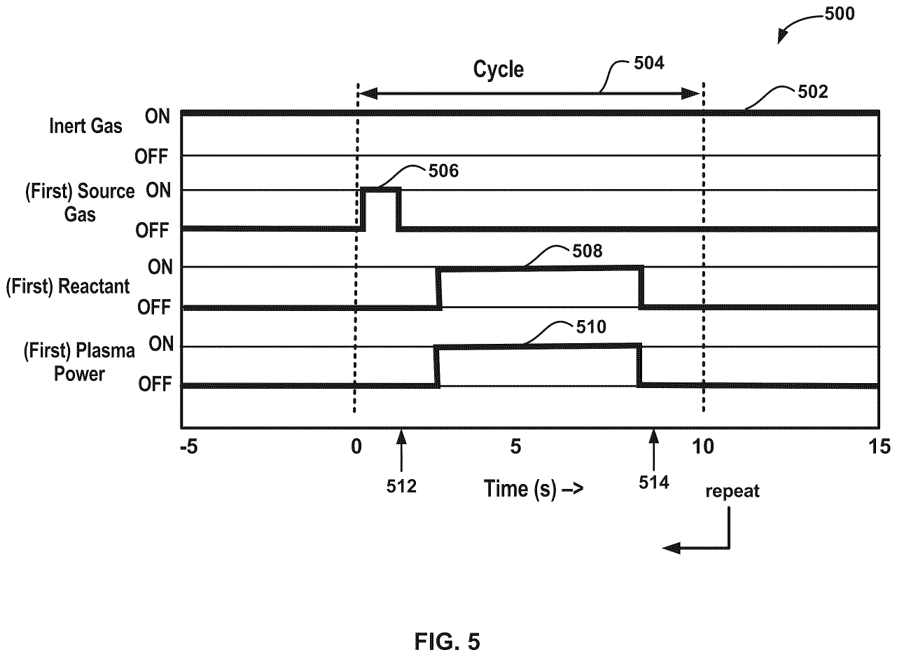

FIGS. 5-8 illustrate exemplary timing sequences suitable for use with step 104 in FIG. 1, as well as methods 200 of FIG. 2, 300 of FIG. 3, and 400 of FIG. 4 described below, in accordance with various examples of the illustrated embodiments. Methods, such as method 100-400, can be used to deposit Mo metal, MON, MoC, MoCN, or a mixture thereof.

As described in more detail below, in accordance with some examples of the exemplary embodiments, supplying the first source gas and supplying the first reactant are performed sequentially. For example, a method can include a PEALD type sequence that includes supplying a first source gas (e.g., MoO₂Cl₂) pulse, followed by a purge, followed by a (e.g., first) reactant plasma (e.g., hydrogen plasma), followed by a purge. This cycle can be repeated X times until desired thickness is reached. Alternatively, the method can include a pulsed PECVD type sequence that includes forming a reactant (e.g., hydrogen) plasma; while the hydrogen plasma is on, pulse a first source gas (e.g., MoO₂Cl₂); keep the reactant (e.g., hydrogen) plasma on for some time; and repeat step of pulsing the first source gas until desired thickness reached; and then switch off the plasma. In accordance with yet additional examples, a pulsed PECVD type sequence could be used. For example, the sequence can include: turn on a continuous first source gas (e.g., MoO₂Cl₂) flow; while the first source gas is flowing, perform a reactant (e.g., hydrogen) plasma pulse; keep the continuous first source gas flowing for some time and repeat the step of flow the plasma pulse X times until desired thickness reached and then switch off the plasma. In some cases, the first reactant is supplied in pulse while (e.g., continuously) supplying the first source gas. In some cases, the first source gas is supplied in pulse while (e.g., continuously) supplying the first reactant. As described herein, the plasma can be a capacitively coupled plasma (CCP) generated between a susceptor and a showerhead. Additionally or alternatively, the plasma can be a plasma generated further upstream of the substrate above the showerhead. This can be an ICP plasma or microwave generated plasma or CCP plasma or other type of plasma.

FIG. 5 illustrates a timing sequence 500 in accordance with examples of the disclosure. Sequence 500 is a plasma-enhanced cyclical deposition process, e.g., a PEALD process. In the illustrated example, sequence 500 includes providing an inert gas (502) continually through one or more deposition cycles (504), supplying a first source gas for a first gas source pulse (506), supplying a first reactant for a first reactant pulse (508), and applying a first power to the reactor for a first power pulse (510). The flowrates, applied power, times, and the like of steps 502 and 506-508 can be as described above. In the illustrated example, the first gas source pulse 506 does not overlap with first reactant pulse 508 or a first power pulse 510. In accordance with examples of the disclosure, the steps of supplying the first reactant and applying the first plasma power overlap in time. For example, as illustrated, a start and/or end time of first reactant pulse 508 and a first power pulse 510 can be substantially the same. As illustrated, sequence 500 can include a purge period 512 and/or a purge period 514, during which the inert gas continues to flow.

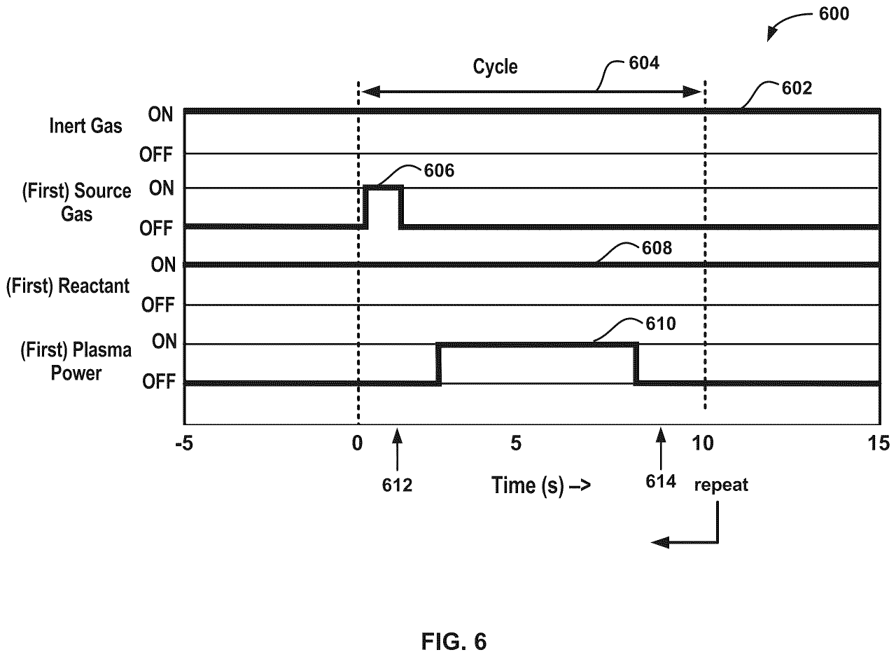

FIG. 6 illustrates a timing sequence 600 in accordance with another plasma-enhanced cyclical deposition process. Timing sequence 600 includes providing an inert gas (602) continually through one or more deposition cycles (604), supplying a first source gas for a first gas source pulse (606), supplying a first reactant continually through one or more deposition cycles 604 (608), and applying a first power to the reactor for a first power pulse (610). The flowrates, applied power, times, and the like of steps 602 and 606-608 can be as described above. In the illustrated example, the first gas source pulse 606 does not overlap with first power pulse 610. In accordance with examples of the disclosure, the steps of supplying the first reactant and applying the first plasma power overlap in time. For example, as illustrated, step 608 can begin before a first deposition cycle and end after the last deposition cycle. As illustrated, sequence 600 can include a purge period 612 and/or a purge period 614, during which the inert gas continues to flow. Timing sequence 600 is similar to timing sequence 500, except the flow of the first reactant is continuous during one or more deposition cycles.

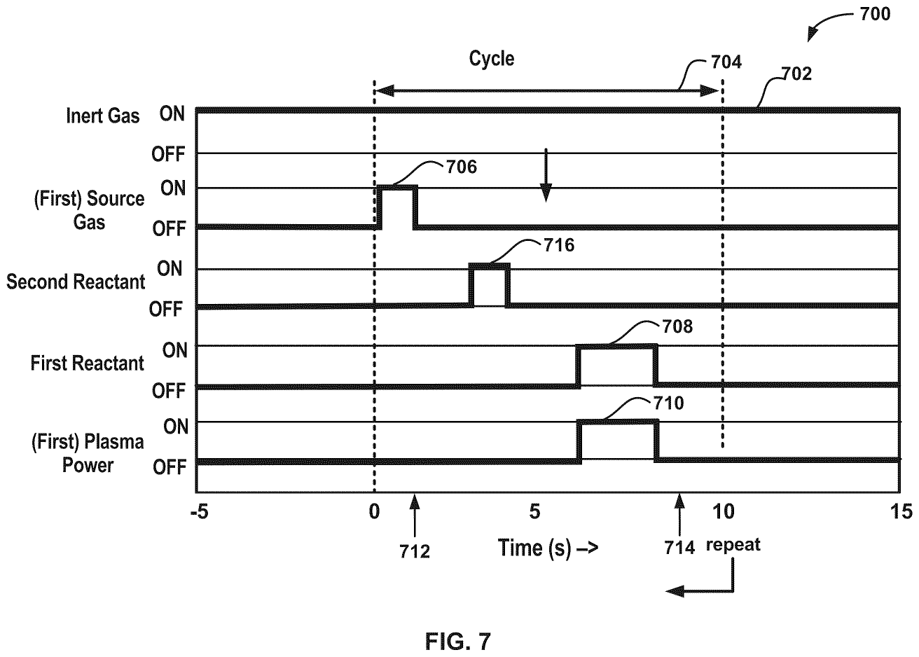

FIG. 7 illustrates another timing sequence 700 in accordance with examples of the disclosure. Timing sequence 700 includes a thermal deposition and plasma treatment process. Timing sequence 700 includes providing an inert gas (702) continually through one or more deposition cycles (704), supplying a first source gas for a first gas source pulse (706), supplying a first reactant for a first reactant pulse (708), applying a first power to the reactor for a first power pulse (710), and supplying a second reactant for a second reactant pulse (716). The flowrates, applied power, times, and the like of steps 702 and 706-710 can be as described above. In the illustrated example, the first gas source pulse 706 does not overlap with first reactant pulse 708 or a first power pulse 710 or second reactant pulse 716. In accordance with examples of the disclosure, the steps of supplying the first reactant and applying the first plasma power overlap in time. For example, as illustrated, a start and/or end time of first reactant pulse 708 and a first power pulse 710 can be substantially the same. Sequence 700 can include a purge period 712 and/or a purge period 714, during which the inert gas continues to flow. In accordance with further examples, the method includes supplying a second reactant and ceasing supplying the second reactant before applying the first power to the reactor. Exemplary second reactants are described below. Pulse times and flowrates of the second reactant can be the same or similar to pulse times and flowrates of the first reactant.

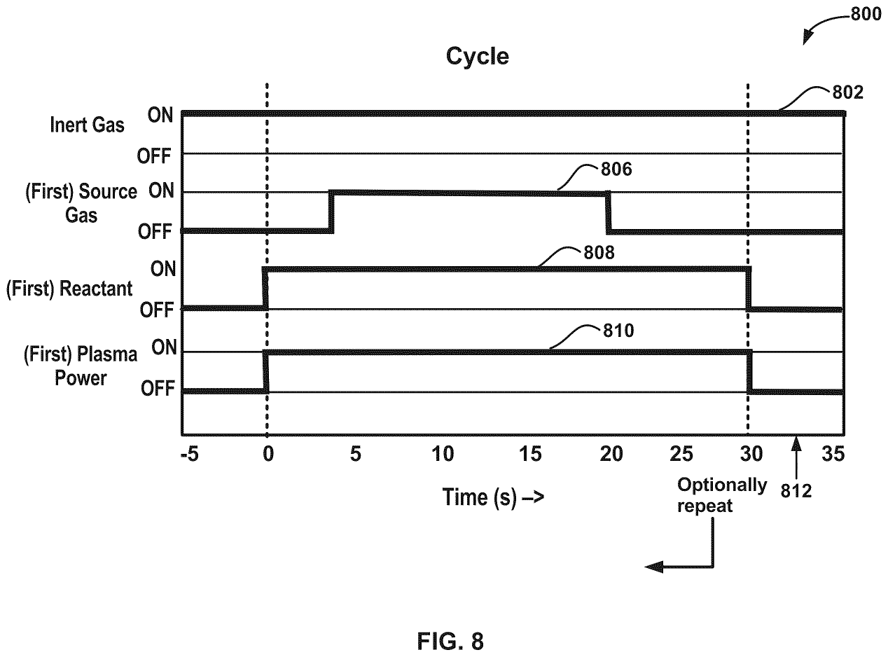

FIG. 8 illustrates yet another timing sequence 800 in accordance with examples of the disclosure. Timing sequence 800 illustrates a CVD cycle that can be repeated. Timing sequence 800 includes providing an inert gas (802) continually through one or more deposition cycles, supplying a first source gas for a first gas source pulse (806), supplying a first reactant for a first reactant pulse (808), and applying a first power to the reactor for a first power pulse (810). The flowrates, applied power, times, and the like of steps 802 and 806-810 can be as described above. In the illustrated example, first gas source pulse 806 overlaps with first reactant pulse 808 and first power pulse 810. In accordance with examples of the disclosure, the steps of supplying the first reactant and applying the first plasma power overlap in time. For example, as illustrated, a start and/or end time of first reactant pulse 808 and a first power pulse 810 can be substantially the same. First gas source pulse 806 can begin after first reactant pulse 808 and first power pulse 810 begin and/or end before first reactant pulse 808 and first power pulse 810 end. Sequence 800 can include a purge period 812, during which the inert gas continues to flow.

FIG. 2 illustrates another method 200 in accordance with examples of the disclosure. Method 200 can be a conformal deposition process, an area selective deposition process, or a topographically selective deposition process. Method 200 can be used to completely fill a recess on a substrate. In some cases, method 200 can include an additional deposition step to fill the recess.

Method 200 includes the steps of providing a substrate (202), optionally performing a preclean (204), optionally performing a pre-deposition treatment (206), supplying one or more source gases (208), supplying a reactant (210), optionally supplying a second reactant (212), supplying a first deposition power (214), optionally performing a post-deposition treatment (216), optionally annealing (218), and optionally chemically mechanically polishing (220). Method 200 can suitably be used to form a contact within insulating material on a substrate surface.

Step 202 can be as described above in connection with step 102 of method 100. By way of example, the substrate can include a recess formed within insulating (e.g., dielectric) material and having a bottom surface that is or includes semiconductive material or a native oxide formed directly on semiconductive material.

During step 204, a native oxide can be removed from a surface of the substrate. For example, a native oxide can be removed from a semiconductor surface at a bottom of a recess. The native oxide can be removed using, for example, one of fluorine-containing gas, fluorine-containing radicals, or a mixture thereof, such as an NF₃ radical (e.g., generated using a remote plasma) and/or an NH₃ based clean. Additionally or alternatively, step 204 can include dipping the substrate into a fluorine-containing liquid, such as a dilute HF acid dip, to remove the native oxide and/or an HF vapor-based clean. Additionally or alternatively, step 204 can include an atomic layer etch process. In accordance with examples of the disclosure, the preclean step 204 includes a dry or vapor-based process that is performed within a (e.g., different) reaction chamber that is clustered with a deposition reaction chamber, such that any air exposure to a precleaned surface is mitigated between the preclean and a subsequent deposition process. The preclean can include a wet preclean process followed by a dry or vapor-based process. The preclean can be performed in a manner, such that an interface between the substrate surface and the subsequently deposited molybdenum-containing material is substantially free of oxygen (e.g., less than 1e¹⁵ or less than 1e¹⁴ oxygen atom/cm²) at the interface or substantially less oxygen than a native oxide on the surface. Step 204 can suitably be performed prior to a deposition process 207.

Pre-deposition treatment step 206 can be performed in the same reaction chamber used for deposition. In accordance with examples of the disclosure, the pre-deposition treatment step 206 includes a hydrogen plasma treatment that includes providing a hydrogen-containing gas to the reaction chamber and applying a plasma power to form activated species from the hydrogen-containing gas within a reaction chamber. The hydrogen-containing gas can be or include, for example, hydrogen, or other hydrogen-containing gas noted herein. A power used to form the plasma during step 206 and/or step 216 can be at least one of a high frequency power, a low frequency power, or a mixture thereof, with an intensity of about 500 W or less. The power during step 206 and/or step 216 can be applied in pulse with duty ratio of about 70% or less (e.g., from about 10% to about 70%). In accordance with examples of the disclosure, the method can include performing the treatment using a hydrogen plasma before forming the molybdenum-containing film, after forming the molybdenum-containing film, or both.

In accordance with examples of method 200, a deposition process 207 is a plasma-assisted deposition process, which can be the same or similar to step 104 described above. Deposition process 207 can be used to deposit, for example, at least one of Mo metal, MON, MoC, MoCN, MoSi or a mixture thereof. Timing sequence 500 in FIG. 5, 600 in FIG. 6, 700 in FIG. 7, or 800 in FIG. 8 can be used for deposition process 207.

During step 208, one or more source gases that include a first source gas comprising molybdenum are supplied to the substrate. The first source gas can be a molybdenum precursor as described above and can be provided using the conditions noted above. In some cases, method 200 can also include providing at least a second source gas.

During step 210, a first reactant is supplied to the substrate. The first reactant can be as described above in connection with step 104 of FIG. 1 and can be supplied using the conditions described above. By way of example, the first reactant includes at least one of hydrogen, nitrogen, or a mixture thereof, such as at least one of H₂, NH₃, NH₄, N₂H₄, B₂H₆, N₂, silane, or a mixture thereof.

In some cases, a second reactant can be provided during step 212. In accordance with examples of these embodiments, the second reactant is or includes at least one of H₂, diiodoethane (C₂H₂I₂), silane, disilane, trisilane, alkyl silane, alkyl iodide, silicon iodide, or a mixture thereof.

During step 214, a deposition power is applied to form a plasma within the/a reaction chamber. In accordance with examples of these embodiments, the power is at least one of a high frequency power, a low frequency power, or a mixture thereof, with an intensity of about 500 W or less. In accordance with further examples, the power is applied in pulse with duty ratio of about 70% or less or between about 10% and about 70%. A duty cycle can be defined as a percent of plasma power on-time/(on-time+off-time).

Post-deposition treatment step 216 can be used to densify and/or modify material deposited during deposition process 207. Although not separately illustrated in connection with FIG. 2, an alternative deposition process can be a thermal ALD process that can be followed by post-deposition treatment step 216. Step 216 can be performed after one or more deposition cycles and/or after deposition is completed. One particular example is a thermal ALD process using MoEtBz₂ and diiodoethane with an argon and hydrogen plasma treatment after one or more thermal ALD cycles. An exemplary timing sequence for such a process is illustrated in FIG. 7.

Anneal 218 can be used for contact formation between the substrate surface and the deposited molybdenum-containing material. In some cases, the anneal process is a thermal anneal process. A temperature of a substrate during the anneal process can be 500° C. or more or can be between about 400 C and about 650° C. During this step, the deposited molybdenum containing film can mix with substrate material at an interface between the deposited molybdenum-containing material and a surface of the substrate.

During step 220, chemical mechanical planarization can be used to planarize a surface of the substrate. Step 220 can suitably be performed (e.g., directly) after step 218.

FIG. 3 illustrates another method 300 in accordance with examples of the disclosure. Method 300 includes the steps of providing a substrate (302), optionally performing a preclean (304), forming a molybdenum-containing film (306), optionally forming a capping layer (308), annealing (310), forming a metallic film (312), and optionally a chemical mechanical polishing (314).

Steps 302-306 can be the same or similar to steps 202, 204, and 207 described above in connection with FIG. 2, and can optionally include a surface treatment as described above. By way of example, step 306 can include forming a film that includes at least one of Mo, MON, MoCN, MoSi or a mixture thereof. The molybdenum-containing film formed during step 306 can partially fill the recess (e.g., contact opening) on the substrate.

Step 308 of forming a capping layer can include, for example, depositing a layer comprising a metal nitride, such as TiN or MoN or TaN. A thickness of the capping layer can be from about 2 nm to about 20 nm.

After the capping layer is formed, during step 310, a thermal annealing process can be performed. A temperature during the thermal anneal process can be as described above in connection with step 218. For example, a temperature of the thermal anneal can be about 500° C. or more. Additionally or alternatively, a thermal anneal as described herein can be performed after step 312.

During step 312, a metallic film is deposited overlying the molybdenum-containing film (e.g., overlying the capping layer and the molybdenum containing film) to fill the recess. The metallic film can include at least one of molybdenum(Mo), tungsten(W), cobalt(Co), ruthenium(Ru), titanium(Ti), nickel(Ni), platinum(Pt), tantalum(Ta), niobium(Nb), scandium(Sc), or a mixture thereof. Step 312 can suitably include supplying a metallic source gas to the substrate and supplying a second reactant to the substrate.

The metallic source gas comprises at least one of molybdenum(Mo), tungsten(W), cobalt(Co), ruthenium(Ru), titanium(Ti), nickel(Ni), platinum(Pt), tantalum(Ta), niobium(Nb), scandium(Sc), or a mixture thereof. For example, the metallic source gas can be or include a metal halide, a metal oxyhalide, metal organic compounds (e.g., β-diketonates), or organometallic compounds similar to those as described above in connection with molybdenum precursors. The second reactant can include a (e.g., first or second) reactant as described herein.

After the recess is filled with the metallic film, excess metallic film material can be removed using chemical mechanical polishing step 314.

FIG. 4 illustrates yet another method 400 in accordance with examples of the disclosure. Method 400 includes the steps of providing a substrate (402), optionally performing a preclean (404), forming a molybdenum-containing film (406), forming a metallic film (408), optionally annealing (410), and optionally a chemical mechanical polishing (412).

Steps 402 and 404 can be the same or similar to steps 202 and 204, 302 and 304 described above. Step 406 can be the same or similar to step 306 described above, except step 406 is performed using only halogen-free molybdenum precursor(s). For example, the source gas used during step 406 can be or include at least one of MoCO₆, tris(2,2,6,6-tetramethylheptane-3,5-dionato)molybdenum [Mo(thd)₃], bis(ethylbenzene)molybdenum [Mo(EtBz)₂], amide-based molybdenum source, cyclopentadienyl molybdenum [MoCp]-based molybdenum source, dicarbonyl[(1,2,3,4,5-η)-1-methyl-2,4-cyclopentadien-1-yl]nitrosylmolybdenum [CH₃C₅H₄Mo(CO)₂NO], or a mixture thereof. The reactant can include any of the (e.g., first) reactants described above. In accordance with examples, the molybdenum-containing film includes at least one of Mo, MON, MoC, MoCN, or a mixture thereof. The molybdenum-containing film can partially fill the recess.

Step 406 can suitably be used to form a barrier layer between the substrate and the metallic film deposited during step 408. Step 406 can be performed using any of timing sequences described above in connection with FIGS. 5-8. A thickness of the molybdenum-containing film can be less than 10 nm, less than 7 nm, or less than 5 nm.

A temperature and pressure within a reaction chamber during step 406 can be as described above. In some cases, step 406 is performed at a temperature of about 350° C. or less or about 320° C. or less.

Step 408 can be the same or similar to step 312 in FIG. 3 described above. By way of example, step 408 can include forming a metallic film comprising at least one of molybdenum(Mo), tungsten(W), cobalt(Co), ruthenium(Ru), copper (Cu) film, or a mixture thereof on the molybdenum-containing film to fill the recess or the contact opening of the substrate after the molybdenum-containing film is formed. In some cases, step 408 can be a thermal ALD process.

During step 410, the metallic film can be annealed. Step 410 can be the same or similar to step 310 in FIG. 3 described above.

During step 412, chemical mechanical polishing is used to planarize a surface of a substrate.

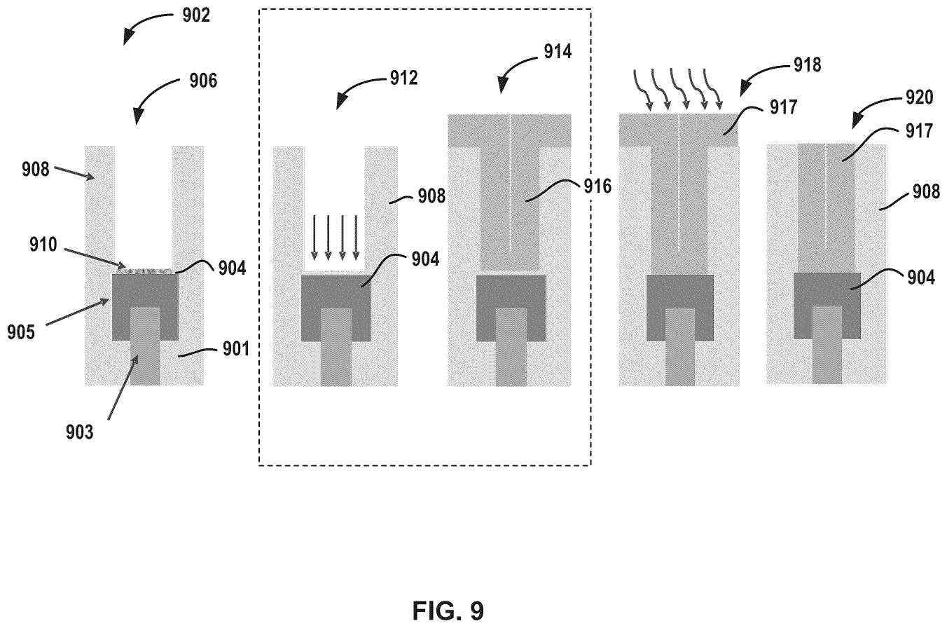

FIGS. 9-12 illustrate structures formed during various method steps in accordance with examples of the disclosure.

FIG. 9 illustrates a structure 902 that includes a semiconductive surface 904 within a recess 906 on a surface of a substrate 901. Recess 906 can be formed within insulating material 908. Structure 902 includes a native oxide 910 overlying semiconductive surface 904 of semiconductor material 905. Structure 902 can also include a semiconductor (e.g., Si) post 903. During a preclean step (e.g., step 404), native oxide 910 is removed, thereby forming a structure 912. FIG. 9 illustrates an example in which a molybdenum-containing film 916 is formed conformally and non-selectively within recess 906 to form structure 914. As noted above, an optional anneal can be performed to form annealed material 917 before a CMP process. Structure 918 is formed during or after an anneal process. Structure 920 is formed after a CMP process. The structures illustrated in FIG. 9 can be formed using, for example, method 100 described above.

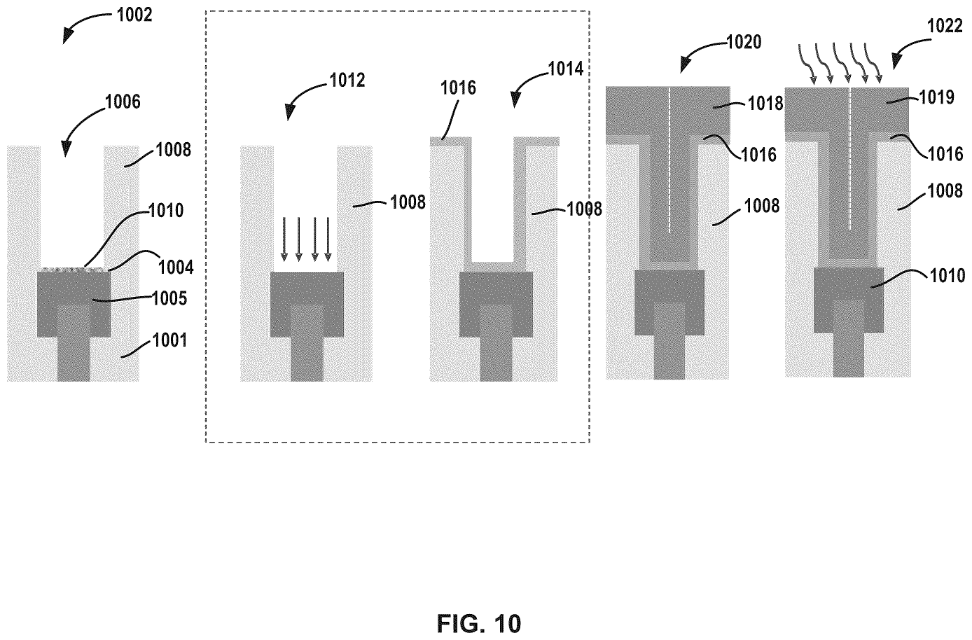

FIG. 10 illustrates a structure 1002 that includes a semiconductive surface 1004 on a semiconductor material 1005 within a recess 1006 on a surface of a substrate 1001. Recess 1006 can be formed within insulating material 1008. Structure 1002 includes a native oxide 1010 overlying semiconductive surface 1004. During a preclean step (e.g., step 404), native oxide 1010 is removed, thereby forming structure 1012. FIG. 10 illustrates another example in which a molybdenum-containing film 1016 is formed conformally and non-selectively within recess 1006 to form structure 1014. In this case, molybdenum-containing film 1016 can be a barrier layer as described herein. After the barrier layer is formed, a subsequent metallic film 1018 can be formed (e.g., directly) on layer 1016 to thereby fill the recess 1006 to, for example, form a contact within recess 1006. As above, an optional anneal (to form anneal material 1019) and/or CMP process can be performed. Structure 1022 is formed during or after an anneal process, such as anneal step 410. The structures illustrated in FIG. 10 can be formed using, for example, method 400 described above.

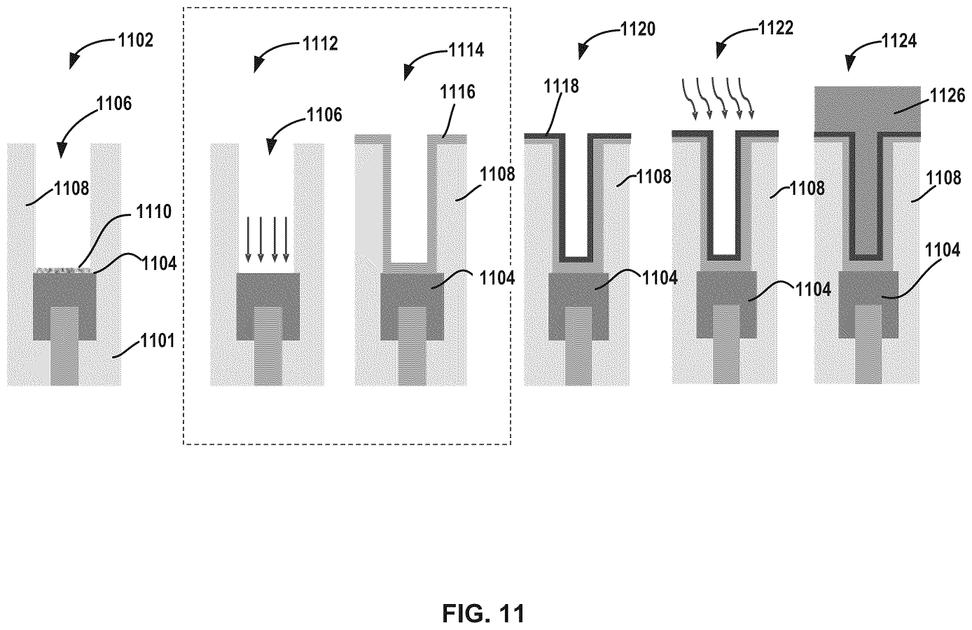

FIG. 11 illustrates a structure 1102 that includes a semiconductive surface 1104 within a recess 1106 on a surface of substrate 1101. Recess 1106 can be formed within insulating material 1108. Structure 1102 includes a native oxide 1110 overlying semiconductive surface 1104. During a preclean step (e.g., step 304), native oxide 1110 is removed, thereby forming structure 1112. FIG. 11 illustrates another example in which a molybdenum-containing film 1116 is formed conformally and non-selectively within recess 1106 to form structure 1114. After the molybdenum-containing film 1116 is formed, a capping layer 1118 is formed (e.g., directly) on molybdenum-containing film 1116 to form structure 1120. Capping layer 1118 can be formed as described above in connection with step 308. Structure 1122 is formed during or after an anneal process. Structure 1124 is formed after a metal fill process to deposit a metallic film 1126, such as metallic film 1018, described above. The structures illustrated in FIG. 11 can be formed using, for example, method 300 described above.

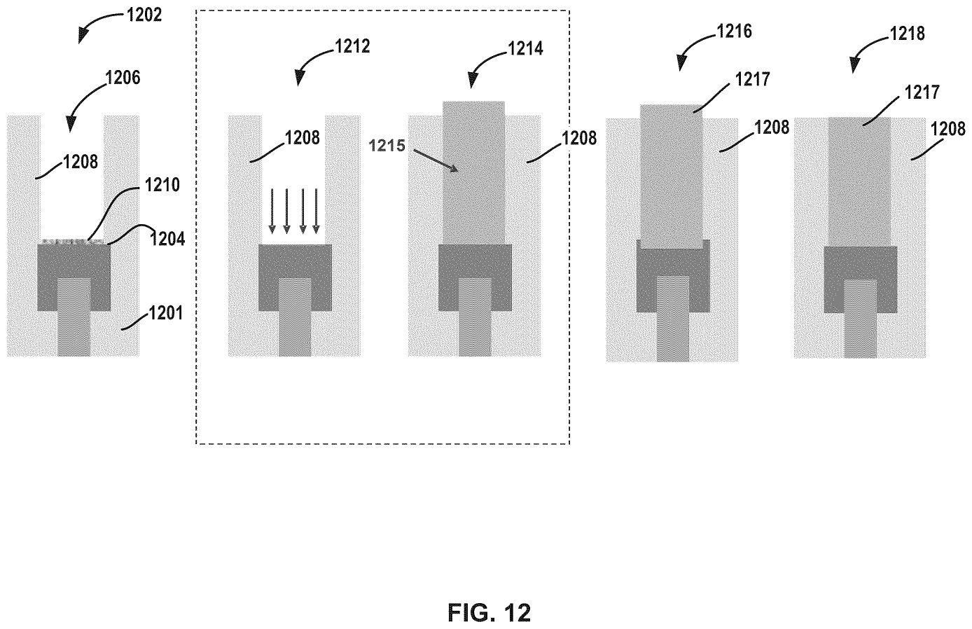

FIG. 12 illustrates a structure 1202 that includes a semiconductive surface 1204 within a recess 1206 on a surface of substrate 1201. Recess 1206 can be formed within insulating material 1208. Structure 1202 includes a native oxide 1210 overlying semiconductive surface 1204. During a preclean step (e.g., step 204), native oxide 1210 is removed, thereby forming structure 1212. FIG. 12 illustrates an example in which a molybdenum-containing film 1215 is selectively formed within recess 1206 to form structure 1214. A structure 1216 including annealed film 1217 is formed during or after an anneal process. Structure 1218 is formed after a CMP process. The structures illustrated in FIG. 12 can be formed using, for example, method 100 and/or 200 described above.

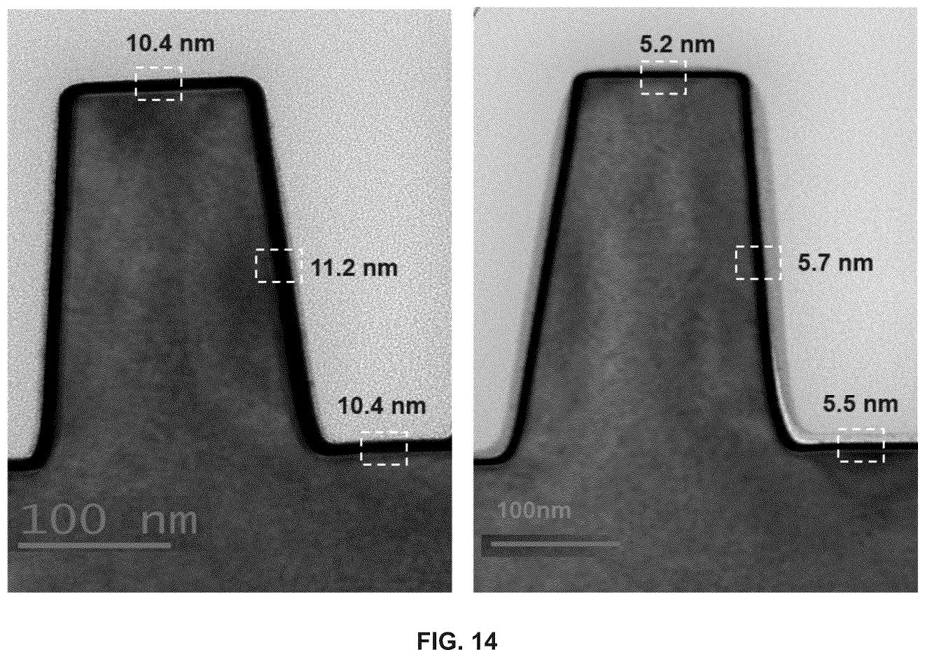

FIG. 14 illustrates TEM images of structures that include a target thickness of (a) 10 nm and (b) 5 nm that were formed according to a method of FIG. 1. As illustrated, the molybdenum-containing film exhibits good conformality.

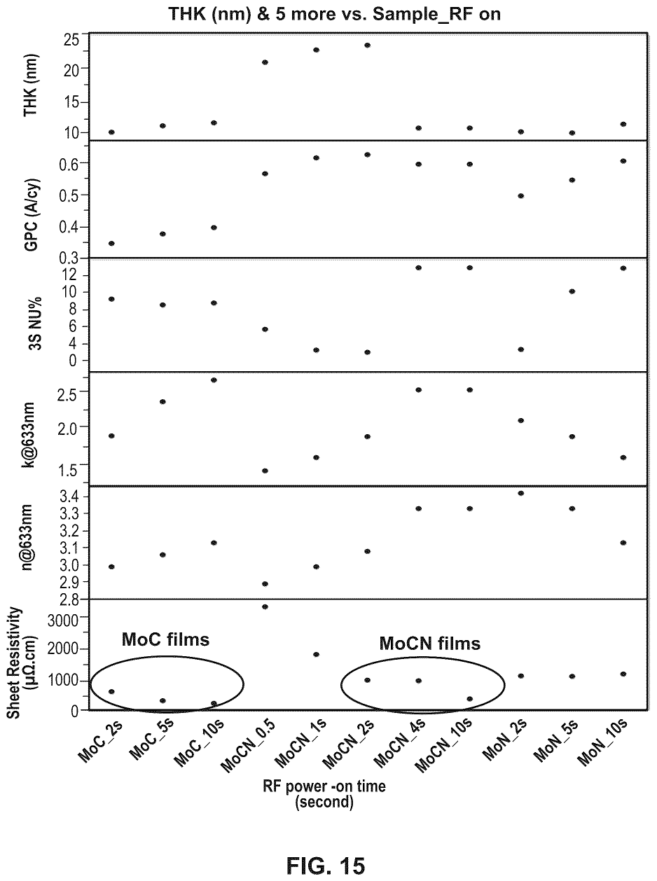

FIG. 15 illustrates sheet resistivity, refractive index (n), extinction coefficient (k), three sigma non-uniformity percent (3S NU %), growth rate per cycle (GPC), and thickness as a function of RF power-on time during a deposition process for molybdenum-containing film: MoC, MoCN, and MoN. As shown, increasing plasma power on time causes a reduction in resistivity of the MoC and MoCN films. An increased trend in n and k leads to low resistivity, which indicates improvement in crystallinity, crystalline phase, and more metal bonding.

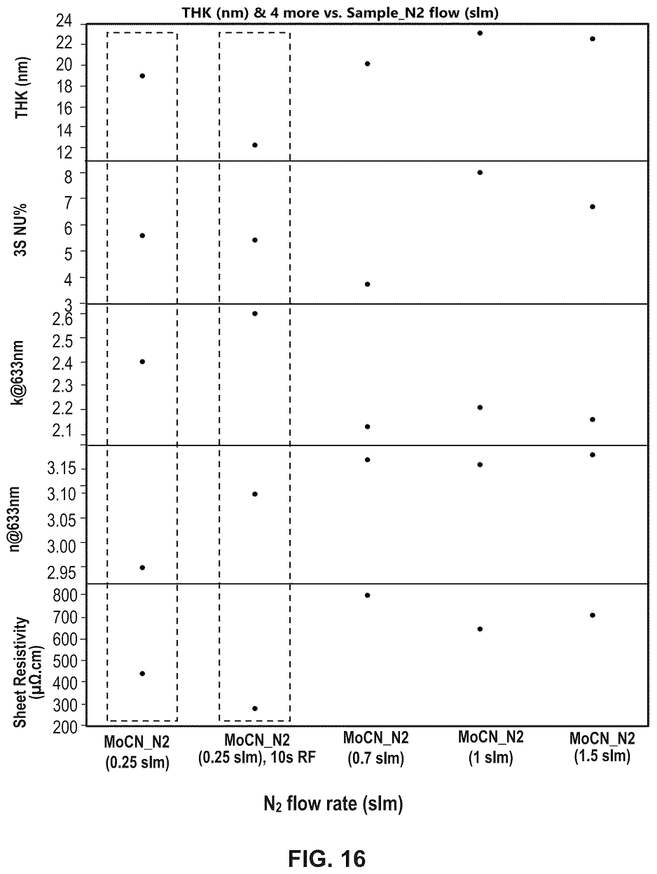

FIG. 16 illustrates sheet resistivity, refractive index (n), extinction coefficient (k), three sigma non-uniformity percent (3S NU %), and thickness as a function of nitrogen flow (e.g., N₂). A low flow rate of N₂ provides a molybdenum containing film with low resistivity. Furthermore, low flow rate of N₂ with longer RF power on time further reduces the resistivity due to the improvement in the crystallinity.

Turning now to FIG. 17, a system 1700 in accordance with exemplary embodiments of the disclosure is illustrated. System 1700 can be used to perform a method as described herein and/or various method steps as described herein.

In the illustrated example, system 1700 includes one or more reactors 1713—each including one or more reaction chambers 1714 therein, a precursor source 1702 in fluid communication via a first flow control valve 1703 and line 1708 with the one or more reaction chambers 1714, a reactant source 1704 in fluid communication via a second flow control valve 1705 and line 1710 with the one or more reaction chambers 1714, a purge source 1706 in fluid communication via a third flow control valve 1707 and line 1712 with the one or more reaction chambers 1714, an exhaust source 1716, and a controller 1718. System 1700 can optionally include a remote plasma source 1720 and/or a direct apparatus 1736, including a plasma power source 1738 to excite a gas (e.g., during a cleaning or deposition step) from one or more sources 1702, 1704 and 1706 or another gas source. Further, as illustrated, system 1700 can include one or more pressure flow controllers or mass flow controllers 1728, 1730, and 1732 associated with lines 1708, 1710, and 1712, respectively. Additionally, to facilitate rapid, relatively large doses of the molybdenum precursor, system 1700 can include an accumulator 1734 in fluid communication between precursor source 1702 and reaction chamber 1714. Accumulator 1734 can allow for higher precursor dose delivery, compared to conventional reactor systems. In one example, accumulator may be a LDS (Liquid Delivery System).

Reaction chamber 1714 can include any suitable reaction chamber, such as a plasma-enhanced atomic layer deposition (ALD) or chemical vapor deposition (CVD) reaction chamber. The reaction chamber 1714 can include a gas distribution system 1722, such as a showerhead (which can form part of a direct or indirect plasma electrode), and a susceptor 1724 to retain a substrate 1726.

Exhaust source 1716 can include one or more vacuum pumps to remove gas from the reaction chamber 1714. Substrate 1726 can be any substrate or structure described herein.

Precursor source 1702 can include a vessel and a molybdenum precursor, such as one or more molybdenum precursors described herein.

Reactant source 1704 can include a vessel and a reactant. The reactant can be or include a first or second reactant as described herein.

Purge source 1706 can include a vessel and one or more purge gases. For example, purge source 806 can include one or more of nitrogen, argon, or the like.

Controller 1718 can include electronic circuitry and software to selectively operate flow control valves 1703-1707, manifolds, heaters, pumps, and other components included in system 1700. Such circuitry and components can operate to introduce precursors, reactants, and purge gases from the respective sources 1702-1706. Controller 1718 can control timing of gas pulse sequences, temperature of the substrate and/or reaction chamber, pressure within the one or more reaction chambers 1714, and various other operations to provide proper operation of system 1700. Controller 1718 can include software to electrically or pneumatically operate flow control valves to provide the precursors from precursor source 1702 and the reactant from reactant source 1704 into one or more reaction chambers 1714. Controller 1718 can also include software to provide purge gases into and out of the one or more reaction chambers 1714.

Controller 1718 can include modules, such as a software or hardware component, e.g., a FPGA or ASIC, which perform certain tasks. A module can advantageously be configured to reside on the addressable storage medium of the control system and be configured to execute one or more processes.

By way of examples, controller 1718 can be configured to operate flow control valves and heaters to: non-selectively or conformally deposit plasma-deposited molybdenum on a first surface (e.g., at a bottom of a gap) on a substrate relative to a second surface (e.g., on a sidewall of the gap) to at least partially fill the gap and thereafter deposit additional molybdenum over the first surface and a second surface. Alternatively, controller 1718 can be configured to selectively deposit molybdenum and thereafter use a plasma-assisted process to non-selectively or conformally deposit molybdenum on the selectively deposited molybdenum.

Other configurations of system 1700 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the one or more reaction chambers 1714. Further, as a schematic representation of an apparatus, many components have been omitted for simplicity of illustration; such components may include, for example, various valves, manifolds, purifiers, heaters, containers, vents, and/or bypasses.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of filling a recess on a surface of a substrate with a molybdenum-containing material comprising:
providing a substrate in a reactor; and
forming a molybdenum-containing film by repeating a cycle comprising:
supplying a first source gas comprising a molybdenum to the substrate;
supplying a first reactant to the substrate; and
applying a first power to the reactor to form a plasma to form activated reactant species that react with the first source gas or a derivative thereof adsorbed on the substrate,
wherein the steps of supplying the first reactant and applying the first plasma power overlap in time.

2. The method of claim 1, wherein the first source gas comprises at least one of MoO₂Cl₂, MoCl₄, MoCl₅, MoF₅, MoCO₆, MoO₂Br₂, tris(2,2,6,6-tetramethylheptane-3,5-dionato)molybdenum [Mo(thd)₃], bis(ethylbenzene)molybdenum [Mo(EtBz)₂], amide-based molybdenum source, cyclopentadienyl molybdenum [MoCp]-based molybdenum source, dicarbonyl[(1,2,3,4,5-η)-1-methyl-2,4-cyclopentadien-1-yl]nitrosylmolybdenum [CH₃C₅H₄Mo(CO)₂NO], or a mixture thereof.

3. The method of claim 1, wherein the first reactant comprises at least one of hydrogen, nitrogen, or a mixture thereof.

4. The method of claim 3, wherein the first reactant comprises at least one of H₂, NH₃, NH₄, N₂H₄, B₂H₆, N₂, silane, or any mixture thereof.

5. The method of claim 1, wherein the method further comprises supplying a second reactant before applying the first power to the reactor.

6. The method of claim 5, wherein the second reactant comprises at least one of H₂, diiodoethane (C₂H₂I₂), silane, disilane, trisiliane, alkyl silane, alkyl iodide, silicon iodide, or a mixture thereof.

7. The method of claim 1, wherein the method further comprises performing a preclean to remove a native oxide from the substrate before forming the molybdenum-containing film.

8. The method of claim 7, wherein the preclean is performed while supplying at least one of fluorine-containing gas, fluorine-containing radicals, or a mixture thereof.

9. The method of claim 7, wherein the preclean is performed by an atomic layer etch process.

10. The method of claim 7, wherein the preclean is performed by dipping the substrate into a fluorine-containing liquid.

11. The method of claim 7, wherein the preclean is performed in a reactor different from the reactor in which the molybdenum-containing film is formed, to mitigate exposing the substrate to air.

12. The method of claim 1, wherein the substrate comprises at least one of a silicon, a silicon germanium doped with at least one of phosphorous (P), boron (B), gallium (Ga), arsenide (As), antimony (Sb), or a mixture thereof, and wherein the molybdenum-containing film contacts the substrate through the recess.

13. The method of claim 1, wherein the method further comprises supplying a second source gas comprising a silicon to the reactor to form a silicon and molybdenum-containing film.

14. The method of claim 1, performing treatment using a hydrogen plasma before forming the molybdenum-containing film, after forming the molybdenum-containing film, or both.

15. The method of claim 1, wherein the method is performed at a temperature range of between about 200° C. and about 400° C.

16. The method of claim 1, wherein the first power is at least one of a high frequency power, a low frequency power, or a mixture thereof, with an intensity of about 500 W or less.

17. The method of claim 16, wherein the first power is applied in pulse with duty ratio of about 70% or less.

18. The method of claim 14, wherein the second power is at least one of a high frequency power, a low frequency power, or a mixture thereof, with an intensity of about 500 W or less.

19. The method of claim 18, wherein the second power is applied in pulse with duty ratio of about 70% or less.

20. The method of claim 1, wherein supplying the first source gas and supplying the first reactant are performed sequentially.

21. The method of claim 1, wherein the first reactant is supplied in pulse while supplying the first source gas.

22. The method of claim 1, wherein the first source gas is supplied in pulse while supplying the first reactant.

23. The method of claim 1, wherein the method further comprises performing a thermal anneal after forming the molybdenum-containing film, followed by performing chemical-mechanical polishing (CMP).

24. The method of claim 23, wherein the thermal anneal is performed at about 500° C. or more.

25. The method of claim 1, wherein the molybdenum-containing film comprises at least one of Mo metal, MoN, MoC, MoCN, MoSi, or a mixture thereof.

26-49. (canceled)
